(19) United States
(12) Patent Application Publication
(10) Pub. No.: US 2006/0105524 A1
(43) Pub. Date: May 18, 2006

(54) Non-volatile device manufactured using ion-implantation and method of manufacture the same

(75) Inventors: Jeong-hee Han, Gyeonggi-do (KR); Hoon-young Cho, Seoul (KR); Chung-woo Kim, Gyeonggi-do (KR); Chan-jin Park, Jeollabuk-do (KR); Jong-soo Oh, Seoul (KR); Ki-hyun Cho, Seoul (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRONICS CO., LTD., Gyeonggi-do (KR)

(21) Appl. No.: 11/190,827

(22) Filed: Jul. 28, 2005

(30) Foreign Application Priority Data
Nov. 15, 2004 (KR) 10-2004-0093005

(51) Int. Cl. H01L 21/336

(52) U.S. Cl. 438/257

(57) ABSTRACT

Embodiments of the invention include a non-volatile memory device manufactured using ion-implantation, and a method of manufacturing the same. A dielectric layer may be formed on a semiconductor substrate, and an ion implantation layer, which may be used as a charge trapping site, may be formed by ion implantation with Si or Ge. Then, an annealing process may be performed. Subsequently, a process for forming a transistor on the dielectric layer may be performed.

### BACKGROUND OF THE DISCLOSURE

This application claims the benefit of Korean Patent Application No. 10-2004-0093005, filed on Nov. 15, 2004, in the Korean Intellectual Property Office, the disclosure of which is incorporated herein in its entirety by reference.

1. Field of the Disclosure

Embodiments of the present disclosure relate to a semiconductor device and, more particularly, to a non-volatile device manufactured using ion-implantation, and a method of manufacturing the same.

2. Description of the Related Art

Non-volatile memory devices, such as EEPROMs, can retain their data even without power. Non-volatile memory devices include a charge trapping layer used to trap charges interposed between the gate of a transistor and a channel such that the threshold voltage can vary.

FIG. 1 is a sectional view of a conventional non-volatile memory device.

Referring to FIG. 1, a gate 20 is formed over a semiconductor substrate 10, a source region 51 and a drain region 55 are formed in the semiconductor substrate 10 on either side of the gate 20, and a channel 11 is formed in the semiconductor substrate 10 between the source and drain regions 51 and 55. The source and drain regions 51 and 55 may have a lightly doped drain (LDD) structure. Further, a charge trapping layer 40, which stores charge, is formed between the gate 20 and the channel 11, and a tunnel dielectric layer 30, in which tunneling of charge occurs and through which charge is injected, is formed below the charge trapping layer 40.

Charge trapped in the charge trapping layer 40 provides an electric field, and by trapping or removing charge this electric field can be changed. The electric field influences the channel 11 below the gate, to vary the threshold voltage Vₜₕ. Charge remains stored in the charge trapping layer 40 because the charge trapping layer 40, or a charge trapping site, is isolated. Therefore, even when power is no longer supplied, data is retained in the device.

In addition, an insulator 45, such as silicon oxide, may be interposed between the charge trapping layer 40 and the gate 20, and spacers 61 and 63 may be formed on the side walls of the gate 20 to create a LDD structure. The spacers 61 and 63 may be different insulators. For example, a spacer may comprise a silicon oxide liner 63, and a silicon nitride layer 61.

FIG. 2 is a circuit diagram illustrating the drain current Id of a conventional non-volatile memory device.

Referring to FIG. 2, the conventional non-volatile memory device may be operated by detecting the drain current I_{d} using the following method. A gate voltage V_{g} is applied to the gate of a transistor (20 shown in FIG. 1), a drain voltage V_{d} is fixed in the drain region (55 shown in FIG. 1), and a source voltage Vₛ of 0V is applied to the source region (51 shown in FIG. 1).

FIG. 3 is a view illustrating erasing and writing operations of a conventional non-volatile memory device.

Referring to FIG. 3, a threshold voltage Vₜₕ has different values according to whether the charge trapping layer 40 is in a write state or an erase state. The write state is when charge is stored in the charge trapping layer 40. That is, the gate voltage V_{g}, which is applied to turn on a channel, varies according to whether charge is stored in the charge trapping layer 40. In detail, as is shown in FIG. 3, in the erase state, the gate voltage V_{g} required to turn on the channel so that the current I_{d} flows is about 0.1V. However, in the write state, the gate voltage V_{g} required to turn on the channel so that the current I_{d} flows is rises to about 2V, due to an increase of the threshold voltage Vₜₕ.

Since non-volatile memory devices use trapped charge in the charge trapping layer (40 shown in FIG. 1) to vary the threshold voltage Vₜₕ, many efforts have been made to improve the charge trapping layer 40. For example, conventionally, a control gate composed of metal or a metal-like material is used as the charge trapping layer 40. In silicon-oxide-nitride-oxide-silicon (SONOS) devices, a charge trapping site in a silicon nitride layer may be used. In addition, nano-crystals, which provide energy quantum wells, have been used to discontinuously control the location of charge and improve reliability.

However, conventionally, the manufacturing process for a charge trapping layer of a non-volatile memory device is very complex, or a memory window is substantially narrow so that only some limited voltages can be applied to the gate 20. That is, the possible voltage range (ΔV) at the gate 20 may be about 0.6V or about 2.2V. Therefore, such a conventional non-volatile memory device has a relatively narrow memory window.

In addition, the above-mentioned method involves a complex process. When a nano-crystal layer is used as the charge trapping layer 40, the nano-crystal layer may be formed using the following method. First, an amorphous-Si layer is etched using islands arranged thereon as an etch mask. Then, (1) the etched amorphous-Si layer is heat-treated to form doted nano-crystals or, (2) a Si-excess silicon oxide layer is heat treated at high temperatures so that doted silicons may be formed in a silicon oxide layer, or, (3) a low-pressure chemical vapor deposition (LPCVD) may be used to form doted silicons.

Therefore, there is a need to develop a non-volatile memory device having a wide memory window and including a charge trapping layer, which is formed using a simple process.

### SUMMARY OF THE DISCLOSURE

Embodiments of the present disclosure provide a method of manufacturing a non-volatile memory device having a wide memory window and including a charge trapping layer, which may be formed using a simple process.

According to an aspect of the present disclosure, there may be provided a method of manufacturing a non-volatile memory device using ion implantation. The method may include: forming a dielectric layer on a semiconductor substrate; ion implanting semiconductor atoms into the dielectric layer to form an ion implantation layer, to be used as a charge trapping site; and forming a gate of a transistor on the dielectric layer.

The dielectric layer may include a silicon oxide layer.

The dielectric layer may be formed to a thickness of about 10 nm to about 50 nm.

The ion implantation may be controlled such that the semiconductor atoms do not penetrate into the semiconductor substrate formed below the dielectric layer.

The ion implanting may be performed using Si⁺ as an ion of the semiconductor atom.

The ion implanting may be performed using Ge⁺ as an ion of the semiconductor atom.

The ion of the semiconductor atom may be ion implanted into the dielectric layer at a dose of about 10¹⁵/cm³ to 10¹⁷/cm³.

After forming the ion implantation layer, the method may further include the operation of annealing the ion implantation layer and the dielectric layer.

The annealing may be performed at about 900° C. to about 1100° C.

The annealing may be performed directly after the ion implantation or after the formation of the gate.

A non-volatile memory device manufactured using the method according an embodiment of the present disclosure may include: a dielectric layer formed on a semiconductor substrate; an ion implantation layer, formed by ion implanting semiconductor atoms into the dielectric layer, to be used as a charge trapping site; a gate of a transistor formed on the dielectric layer; and a source/drain region formed in the semiconductor substrate.

According to the present disclosure, a non-volatile memory device manufactured using ion-implantation, and a method of manufacturing the same may be provided.

### BRIEF DESCRIPTION OF THE DRAWINGS

The above and other features and advantages of embodiments of the present disclosure will become more apparent by describing in detail exemplary embodiments thereof with reference to the attached drawings in which:

FIG. 1 is a sectional view of a conventional non-volatile memory device;

FIG. 2 is a circuit diagram illustrating the flow of drain current I_{d} of a conventional non-volatile memory device;

FIG. 3 is a view illustrating erasing and writing operations of a conventional non-volatile memory device;

FIG. 4 is a sectional view illustrating the operation of forming a dielectric layer on a semiconductor substrate according to an embodiment of the present invention;

FIG. 5 is a sectional view illustrating the operation of ion implanting semiconductor atoms into the dielectric layer according to an embodiment of the present disclosure;

FIG. 6 is a sectional view illustrating the operation of annealing the ion implantation layer according to an embodiment of the present disclosure;

FIG. 7 is a sectional view illustrating the operation of forming a gate of a transistor on the dielectric layer according to an embodiment of the present disclosure;

FIG. 8 is a graph of normalized capacitance C/Cₒₓ with respect to applied voltage V, to explain the effect of an extended memory window according to an embodiment of the present disclosure; and

FIGS. 9 through 12 are graphs of normalized capacitance C/Cₒₓ with respect to applied voltage V, to explain variables affecting the expansion of a memory window according to an embodiment of the present disclosure.

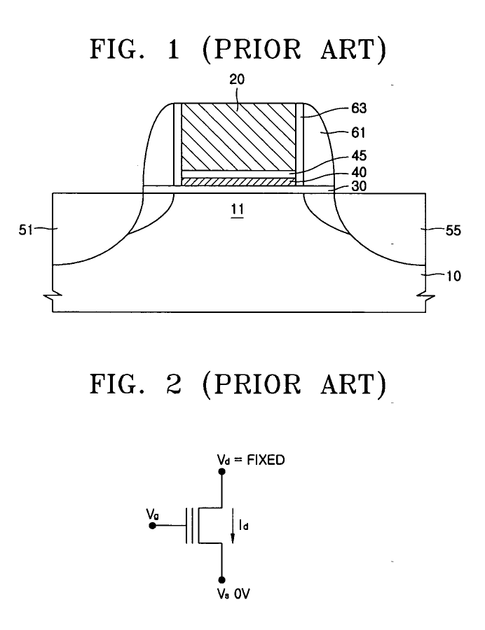

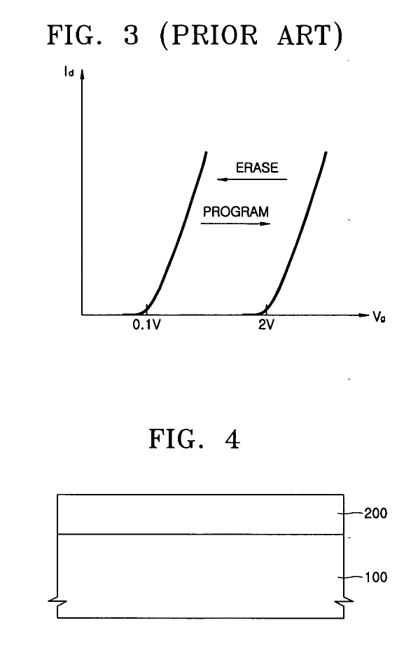

### DETAILED DESCRIPTION OF EXEMPLARY EMBODIMENTS OF THE DISCLOSURE

Embodiments of the present invention will now be described more fully with reference to the accompanying drawings, in which the embodiments are shown. The invention may, however, be embodied in many different forms, and should not be construed as being limited to the embodiments set forth herein.

In an embodiment of the present disclosure, a dielectric layer formed on a semiconductor substrate may be used as an insulator, and an ion implantation layer may be used as a charge trapping layer. In this case, the ion implantation layer may be formed by implanting ionized semiconductor atoms, such as Si⁺ or Ge⁺, into the dielectric layer, and then performing annealing. Ion implantation may be controlled such that ions are substantially implanted only into the dielectric layer. As a result, the annealed ion implantation layer may be formed only in the dielectric layer.

FIGS. 4 through 7 are sectional views illustrating a non-volatile memory device according to an embodiment of the present disclosure.

FIG. 4 is a sectional view illustrating the operation of forming a dielectric layer 200 on a semiconductor substrate 100. Referring to FIG. 4, the dielectric layer 200 may be formed on the semiconductor substrate 100, for example, a silicon single crystalline substrate. The thickness of the dielectric layer 200 may vary according to the scale of the final device. For example, the dielectric layer 200 may have a thickness of about 50 nm or less. In detail, the dielectric layer 200 may have a thickness of about 10 nm to about 50 nm, preferably about 30 nm. The dielectric layer 200 may be formed of a dielectric material having insulating characteristics, such as silicon oxide.

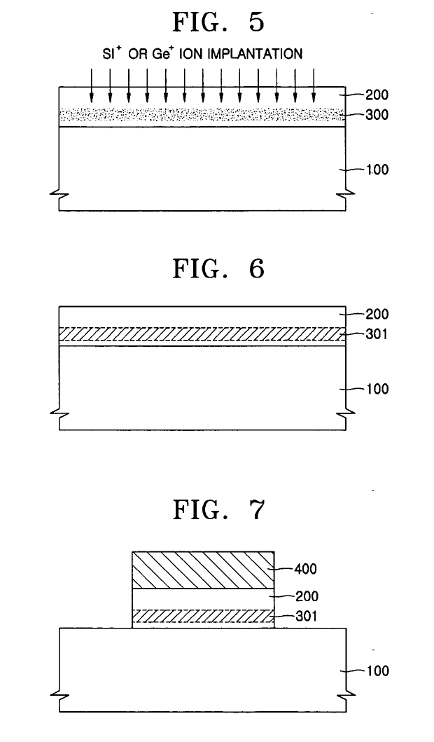

FIG. 5 is a sectional view illustrating the operation of ion implanting semiconductor atoms into the dielectric layer 200 according to an embodiment of the present disclosure. Referring to FIG. 5, semiconductor atoms, such as Si⁺ or Ge⁺, may be ion implanted into the dielectric layer 200. As a result, an ion implantation layer 300 may be formed inside the bulky dielectric layer 200.

At this time, the energy of the ion implantation may be adjusted such that the ions are implanted into the dielectric layer 200 but do not penetrate to the underlying semiconductor substrate 100, so that the ion implantation layer 300 exists only in the dielectric layer 200. For example, the energy for the ion implantation may be about 15 KeV.

In addition, the ion implantation may be performed with a high dose, to attain a sufficient memory window. At this time, however, the dose may be adjusted so as not to impair the insulating characteristics of the dielectric layer 200. The dose may be in the range of about 10¹⁵/cm³ to about 10¹⁷/cm³, preferably about 1.0×10⁶/cm³. Such a dose may ensure that a wide memory window can be obtained.

The Si⁺ or Ge⁺, which may be ion-implanted to form the ion implantation layer 300, functions as a charge trapping site. Such ion-implanted ions have relatively low energy band levels, as does a metal-like layer, allowing them to trap charge. Therefore, the ion implantation layer 300 may have a large memory window compared to a conventional nano-crystal memory. For example, a memory window of over 20V may be obtained.

FIG. 6 is a sectional view illustrating the operation of annealing the ion implantation layer 300 according to an embodiment of the present disclosure. Referring to FIG. 6, after Si⁺ or Ge⁺ is ion implanted, the ion implantation layer may be annealed to form an annealed ion implantation layer 301. The annealing process may help to improves the memory window and stabilize the ion implantation layer 301. In addition, the annealing may cure damage to the dielectric layer 200 caused by the ion implantation and may help to evenly diffuse the ions implanted into the dielectric layer 200.

The annealing may be performed at a temperature of about 900° C. to about 1,100° C., preferably about 1,000° C.

FIG. 7 is a sectional view illustrating the operation of forming a gate 400 of a transistor on the dielectric layer 200 according to an embodiment of the present disclosure. Referring to FIG. 7, after the ion implantation layer 301 is formed in the dielectric layer 200, subsequent processes for forming a transistor can be further performed on the dielectric layer 200. For example, a gate 400 may be deposited on the dielectric layer 200 and patterned, and then a source/drain region may be formed.

Meanwhile, referring to FIG. 6, even though the annealing process can be performed right after the ion implantation layer (300 shown in FIG. 5) is formed, it can also be performed after a process for forming the transistor, such as a process for forming the gate 400.

As is described above, the non-volatile memory device according to the present embodiment may have a larger memory window than a conventional nano-crystal memory device. In addition, in the present embodiment, a charge trapping site or a charge trapping layer may be formed by ion implantation. Therefore, uniformity of dot size and randomness of dots are no longer elements that need to be considered. Further, there is no need for complex deposition techniques, masks, new materials, or new equipment. Conventionally, it is difficult to obtain a dot having a diameter of 10 nm or smaller. This causes problems in forming a gate that is expected to have a length of less than 50 nm. However, when the present invention is applied, the gate length may be sufficiently reduced to below about 50 nm, because ion implantation may be used.

The increase in memory window due to the ion implantation layer according to an embodiment of the present disclosure is identified by measuring a normalized capacitance with respect to an applied voltage V.

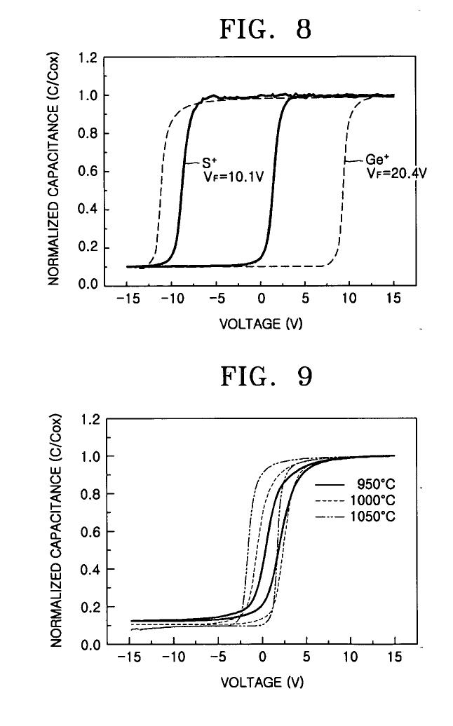

FIG. 8 is a graph of normalized capacitance C/Cox with respect to applied voltage V. The graph is used to explain the effect of an extended memory window according to an embodiment of the present disclosure. Referring to FIG. 8, when Ge⁺ is ion implanted, a memory window of about 20.4V may be attained; and when Si⁺ is ion implanted, a memory window of about 10.1V may be attained. These memory windows are much larger than the conventional memory window of 0.6V to 2.2V. At this time, the dose density of the ions may be about 10¹⁶/cm³, and the normalized capacitance may be measured at a temperature of about 300 K.

Meanwhile, the increase in memory window due to the ion implantation layer according to an embodiment of the present disclosure may be dependent on the dose of the implanted ions.

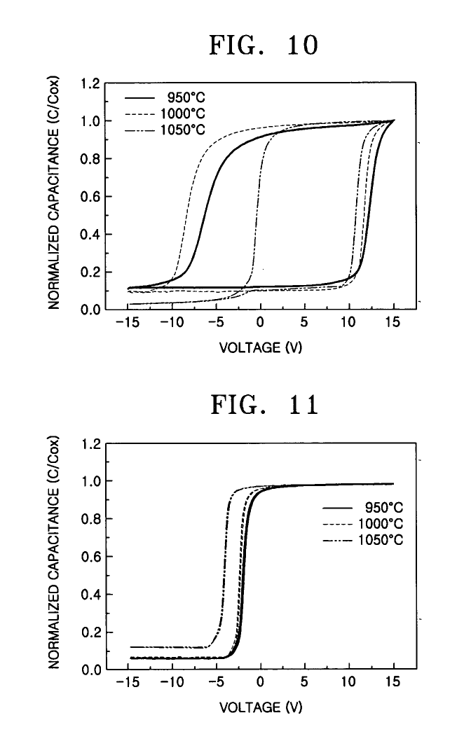

FIGS. 9 through 12 are graphs of normalized capacitance C/COX with respect to applied voltage V. The graphs may be used to explain variables affecting the increased memory window according to an embodiment of the present disclosure.

FIGS. 9 through 12 are graphs of normalized capacitance C/Cox with respect to applied voltage V. In each case, a silicon oxide (SiO₂) layer was formed on an n-Si substrate to a certain thickness, and G⁺ was ion implanted into the silicon oxide layer at a certain dose.

For FIG. 9, the thickness was 30 nm, and the dose was 5.0×10¹⁵/cm³.

For FIG. 10, the thickness was 30 nm, and the dose was 1.0×10¹⁶/cm³.

For FIG. 11, the thickness was 50 nm, and the dose was 5.0×10¹⁵/cm³.

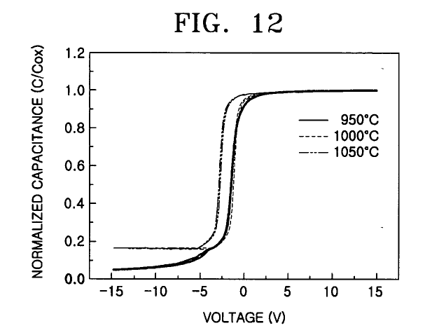

For FIG. 12, the thickness was 50 nm, and the dose was 1.0×10¹⁶/cm³.

In each case, samples were annealed at 950° C., 1000° C., and 1050° C.

Referring to FIGS. 9 and 10, the window memory may be substantially increased when G⁺ is ion implanted at a dose of 1.0×10¹⁶/cm³, especially when annealing is performed at a temperature of about 1000° C. In general, the increase of the memory window is dependent on the temperature for annealing.

When FIGS. 9 and 10 are compared with FIGS. 11 and 12, it is confirmed that G⁺ implantation may be dependent on the thickness of the silicon oxide layer. In detail, the memory window is substantially increased when the silicon oxide layer is relatively thin. Specifically, the memory window is larger when the thickness of the silicon oxide layer is about 30 nm than when the thickness of the silicon oxide layer is about 50 nm.

Meanwhile, referring to FIG. 5, the ion implantation layer 300 is formed of the implanted ions array. At this time, the ion implantation may be controlled such that the implanted ions do not exist outside the dielectric layer 200. That is, it is preferred that those implanted ions exist only inside the dielectric layer 200. Substantially, the concentration profile of the ion implanted Ge indicates that Ge exists only in the dielectric layer.

A non-volatile device memory device according to the present disclosure may attain a larger memory window than a conventional non-volatile memory device, such as a nano-crystal memory device. Ions implanted into a dielectric layer have relatively low energy band levels, as does a metal-like layer. Therefore, the memory window can be more than 20V.

In addition, according to the present invention, a charge trapping site can be formed using only ion implantation, without needing complex etch masks and deposition processes. Further, even when the gate length is less than about 50 nm, the ion implantation layer can be used as a charge trapping layer. The use of ion implantation removes the need to consider uniformity of dot size and randomness of dots.

While embodiments of the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A method of manufacturing a non-volatile memory device, the method comprising:
forming a dielectric layer on a semiconductor substrate;
ion implanting semiconductor atoms into the dielectric layer to form an ion implantation layer, to be used as a charge trapping site; and
forming a gate of a transistor on the dielectric layer.

2. The method of claim 1, wherein the dielectric layer comprises a silicon oxide layer.

3. The method of claim 1, wherein the dielectric layer is formed to a thickness of about 10 nm to about 50 nm.

4. The method of claim 1, wherein the ion implantation is controlled such that the semiconductor atoms do not penetrate into the semiconductor substrate below the dielectric layer.

5. The method of claim 1, wherein the ion implanting is performed using Si⁺ as an ion of the semiconductor atom.

6. The method of claim 1, wherein the ion implanting is performed using Ge⁺ as an ion of the semiconductor atom.

7. The method of claim 1, wherein the ion of the semiconductor atom is ion implanted into the dielectric layer at a dose of about 10¹⁵/cm³ to about 10¹⁷/cm³.

8. The method of claim 1, further comprising the operation of annealing the ion implantation layer and the dielectric layer.

9. The method of claim 8, wherein the annealing is performed at about 900° C. to about 1100° C.

10. The method of claim 8, wherein the annealing is performed directly after the ion implantation or after the formation of the gate.

11. A non-volatile memory device comprising:
a dielectric layer formed on a semiconductor substrate;
an ion implantation layer, formed by ion implanting semiconductor atoms into the dielectric layer, to be used as a charge trapping site;
a gate of a transistor formed on the dielectric layer; and
a source/drain region formed in the semiconductor substrate.

12. The device of claim 11, wherein the dielectric layer comprises a silicon oxide layer.

13. The device of claim 11, wherein the dielectric layer has a thickness of about 10 nm to about 50 nm.

14. The device of claim 11, wherein the ion implanting is performed using Si⁺ as an ion of the semiconductor atom.

15. The device of claim 11, wherein the ion implanting is performed using Ge⁺ as an ion of the semiconductor atom.

16. The device of claim 11, wherein the ion implantation layer comprises an ion of the semiconductor atom ion implanted at a dose of about 10¹⁵/cm³ to about 10¹⁷/cm³.
